(19) United States
(12) Patent Application Publication
(10) Pub. No.: US 2009/0243069 A1
(43) Pub. Date: Oct. 1, 2009

(54) INTEGRATED CIRCUIT PACKAGE SYSTEM WITH REDISTRIBUTION

(76) Inventors: Zigmund Ramirez Camacho, Singapore (SG); Lionel Chien Hui Tay, Singapore (SG); Henry Descalzo Bathan, Singapore (SG); Abelardo Jr. Advincula, Singapore (SG)

Correspondence Address: LAW OFFICES OF MIKIO ISHIMARU, 333 W. EL CAMINO REAL, SUITE 330, SUNNYVALE, CA, 94087, US

(21) Appl. No.: 12/055,612

(22) Filed: Mar. 26, 2008

(51) Int. Cl. H01L 23/12; H01L 21/58

(52) U.S. Cl. 257/686; 438/108; 438/109; 257/690; 257/E23.169; 257/E23.003; 257/E21.511

(57) ABSTRACT

An integrated circuit package system comprising: forming a base package having a molded top; providing a surface contact on the base package; and patterning a redistribution layer on the molded top for coupling the surface contact.

### TECHNICAL FIELD

The present invention relates generally to integrated circuit packaging, and more particularly to a system for stacking known good integrated circuit packages.

### BACKGROUND ART

Personal electronic devices such as cell phones, pagers, personal digital assistants, computers, and many other products utilize a number of microelectronic devices. A packaged microelectronic device can include a microelectronic die, an interposer substrate or lead frame attached to the die, and a molded casing around the die. The microelectronic die generally has an integrated circuit and a number of bond-pads coupled to the integrated circuit. The bond-pads are coupled to terminals on the interposer substrate or lead frame. The interposer substrate can also include ball-pads coupled to the terminals by traces in a dielectric material. An array of solder balls is configured so that each solder ball contacts a corresponding ball-pad to define a “ball-grid” array. Packaged microelectronic devices with ball-grid arrays are generally higher grade packages that have lower profiles and higher pin counts than conventional chip packages that use a lead frame.

Some of the popular ball-grid array packages may include Multiple Chip Module/Ball Grid Array (MCM/BGA), Cavity Down Ball Grid Array (Cavity Down BGA), Flip Chip Ball Grid Array (FC BGA), Flip Chip Pin Grid Array (FC PGA) and Ball Grid Array which have active components and passive components. These devices are highly efficient and low cost. They provide minimization and higher packaging density of a semiconductor package that most electronic companies continuously attempt to achieve. While the ball grid array packages are very robust, they take up larger amounts of area in the targeted application.

Another process for packaging microelectronic devices is wafer-level packaging. In wafer-level packaging, a number of microelectronic dice are formed on a wafer and then a redistribution layer is formed on top of the dice. The redistribution layer may have a dielectric layer, a plurality of ball-pad arrays on the dielectric layer, and traces coupled to individual ball-pads of the ball-pad arrays. Each ball-pad array is arranged over a corresponding microelectronic die, and the ball-pads in each array are coupled to corresponding bond-pads on the die by the traces in the redistribution layer. After forming the redistribution layer on the wafer, a stenciling machine deposits discrete blocks of solder paste onto the ball-pads of the redistribution layer. The solder paste is then reflowed to form solder balls or solder bumps on the ball-pads. After formation of the solder balls on the ball-pads, the wafer can be cut to singulate the dies. Microelectronic devices packaged at the wafer-level can have high pin counts in a small area, but they are not as robust as devices packaged at the die-level.

Packaged microelectronic devices can also be produced by “build-up” packaging. For example, a sacrificial substrate can be attached to a panel including a plurality of microelectronic dies and an organic filler that couples the dies together. The sacrificial substrate is generally a ceramic disc, and it is attached to the active side of the microelectronic dies. Next, the back side of the microelectronic dies is thinned, and then a ceramic layer is attached to the back side. The sacrificial substrate is then removed from the active side of the dies and build-up layers or a redistribution layer can be formed on the active side of the dies. Packaged devices using a build-up approach on a sacrificial substrate provide high pin counts in a small area and a reasonably robust structure.

The build-up packaging process, however, has several drawbacks. For example, the process is relatively expensive and may not be used on equipment set up for circular substrates. Furthermore, the resulting packaged microelectronic devices do not have an effective mechanism for dissipating heat, which can significantly impair the electrical performance of the device.

The above-mention semiconductor packages generally include a substrate for supporting a semiconductor chip or for acting as an intermediate carrier between the semiconductor chip and a printed circuit board. Furthermore, the passive components are disposed in an extra space and on an extra area. The most difficult issues to address are the final line yield and the area density of the electronic design. The final line yield may be reduced by including a single bad die in a multi-chip configured package. This must be addressed by adding testing steps to the assembly process. The issue of area reduction is far more difficult to address.

Thus, a need still remains for an integrated circuit package system with redistribution. In view of the ever-increasing demand for high function personal electronic devices, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to save costs, improve efficiencies and performance, and meet competitive pressures, adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit package system including: forming a base package having a molded top; providing a surface contact on the base package; and patterning a redistribution layer on the molded top for coupling the surface contact.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a top view of an integrated circuit package system with distribution, in an embodiment of the present invention;

FIG. 2 is a cross-sectional view of the integrated circuit package system with distribution of FIG. 1 along the section line 2-2;

FIG. 3 is a cross-sectional view of an integrated circuit package system with distribution, in a first alternative embodiment of the present invention;

FIG. 4 is a top view of the integrated circuit package system of FIG. 3;

FIG. 5 is a cross-sectional view of an integrated circuit package system in a further embodiment of the present invention;

FIG. 6 is a cross-sectional view of an integrated circuit package system in a further embodiment of the present invention;

FIG. 7 is a cross-sectional view of an integrated circuit package system in a package on package stack;

FIG. 8 is a cross-sectional view of an integrated circuit package system in a package in package stacked device;

FIG. 9 is a top view of an integrated circuit package system for fine pitch package attachment;

FIG. 10 is a cross-sectional view of the integrated circuit package system, of FIG. 9, in a device stack;

FIG. 11 is a cross-sectional view of a package on package stack utilizing the integrated circuit package system;

FIG. 12 is a perspective view of an integrated circuit package system with redistribution, in an embodiment of the present invention;

FIG. 13 is a perspective view of an integrated circuit package system with redistribution, in an embodiment of the present invention;

FIG. 14 is a perspective view of an integrated circuit package system with redistribution, in a second alternative embodiment of the present invention;

FIG. 15 is a cross-sectional view of an integrated circuit package system in a third alternative embodiment of the present invention;

FIG. 16 is a cross-sectional view of an integrated circuit package system in a first optional configuration of the third alternative embodiment of the present invention;

FIG. 17 is a cross-sectional view of an integrated circuit package system in a second optional configuration of the third alternative embodiment of the present invention;

FIG. 18 is a cross-sectional view of an integrated circuit package system, in an alternative embodiment of the present invention;

FIG. 19 is a cross-sectional view of an integrated circuit package system in an interconnect phase of manufacturing;

FIG. 20 is a cross-sectional view of an integrated circuit package system in a molding phase of manufacturing;

FIG. 21 is a cross-sectional view of an integrated circuit package system in a fourth alternative embodiment of the present invention;

FIG. 22 is a top view of the integrated circuit package system of FIG. 21;

FIG. 23 is a cross-sectional view of an integrated circuit package system in a fifth alternative embodiment of the present invention;

FIG. 24 is a top view of the integrated circuit package system of FIG. 23;

FIG. 25 is a cross-sectional view of an integrated circuit package stack utilizing the present invention;

FIG. 26 is a cross-sectional view of an integrated circuit device stack utilizing the present invention;

FIG. 27 is a cross-sectional view of an integrated circuit package utilizing the present invention;

FIG. 28 is a perspective view of an integrated circuit package system with redistribution, in an embodiment of the present invention;

FIG. 29 is a cross-sectional view of an integrated circuit application of the present invention; and

FIG. 30 is a flow chart of an integrated circuit package system for manufacturing the integrated circuit package system with redistribution in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs. Where multiple embodiments are disclosed and described, having some features in common, for clarity and ease of illustration, description, and comprehension thereof, similar and like features one to another will ordinarily be described with like reference numerals.

For expository purposes, the term “horizontal” as used herein is defined as a plane parallel to the plane or surface of the package substrate or lead frame, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements. The term “system” as used herein means and refers to the method and to the apparatus of the present invention in accordance with the context in which the term is used. The term “processing” as used herein includes stamping, forging, patterning, exposure, development, etching, cleaning, and/or removal of the material or laser trimming as required in forming a described structure.

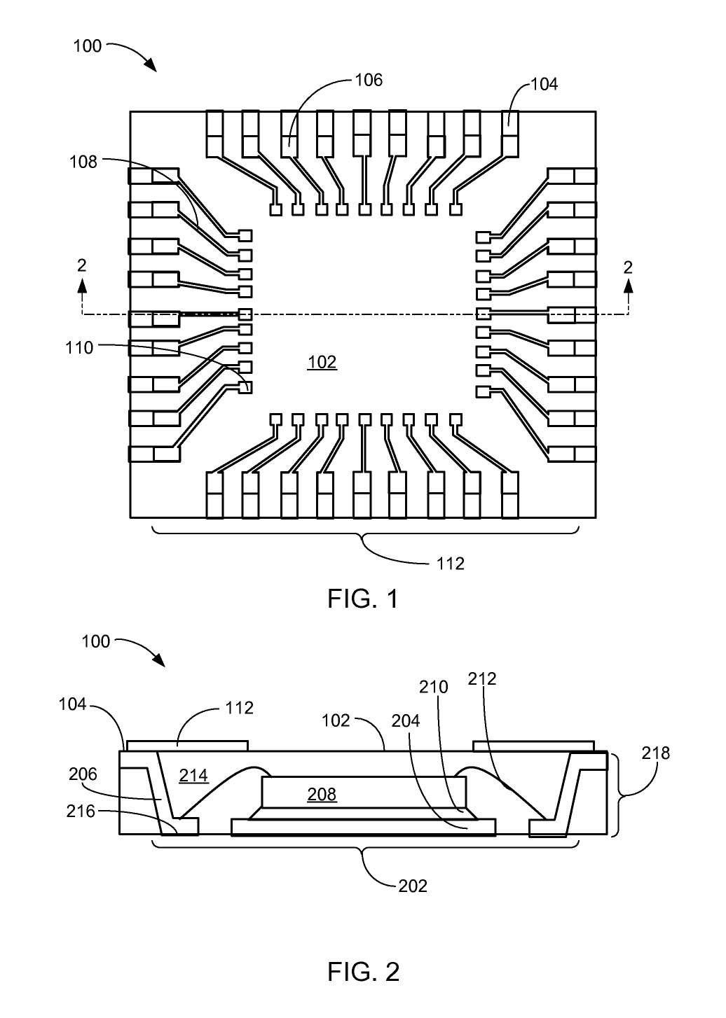

Referring now to FIG. 1, therein is shown a top view of an integrated circuit package system 100 with distribution, in an embodiment of the present invention. The top view of the integrated circuit package system 100 depicts a molded top 102, such as an epoxy molding compound, having surface contacts 104 distributed around the perimeter. The surface contacts 104 may be made of copper or nickel plated copper. A redistribution contact 106 may be formed on the surface contact 104. The redistribution contact 106 may be formed of aluminum (Al), copper (Cu), other metal, or an alloy thereof.

A distribution trace 108 may be patterned on the surface of the molded top 102. A redistribution chip pad 110 may be formed at the end of the distribution trace 108. The redistribution chip pads 110 may be formed in a pattern to align with the contacts of another integrated circuit (not shown). The combination of the redistribution contact 106, the distribution trace 108 and the redistribution chip pads 110 may form a redistribution layer 112. The redistribution layer 112 may be characterized by a conductive layer or layers applied over an integrated circuit and in direct electrical contact with the native input/output ports for the purpose of relocating the input/output ports. A section line 2-2 may depict the position and view angle of FIG. 2.

The redistribution layer 112 may be patterned by a resist layer (not shown) and formed by chemical vapor deposition (CVD), an evaporation process, or sputtering. This process may be applied to any packaged device without changing the process flow or internal structure of the base integrated circuit. The process may further be applied to the sloped or vertical surfaces of the base package by the use of a shape conforming resist.

It is understood that the number and position of the redistribution chip pads 110 is an example only the actual number and position may be different. It is further understood that having the redistribution layer 112 attached to every one of the surface contact 104 is also an example. The configuration of the redistribution chip pads 110, the distribution trace 108, and the redistribution contacts 106 will depend on the type of device (not shown) is intended to mount thereon.

Referring now to FIG. 2, therein is shown a cross-sectional view of the integrated circuit package system 100 with distribution of FIG. 1 along the section line 2-2. The cross-sectional view of the integrated circuit package system 100 depicts the molded top 102 having the redistribution layer 112 formed thereon. A lead frame 202 may have a die attach pad 204 and lead fingers 206.

An integrated circuit die 208 may be mounted over the die attach pad 204 by an adhesive 210, such as a die attach material. An electrical interconnect 212 may couple the integrated circuit die 208 to the lead frame 202. A molded package body 214, such as an epoxy molding compound, may be formed around the lead frame 202, the integrated circuit die 208 and the electrical interconnects 212.

The lead fingers 206 may protrude through the molded package body 214. The surface contacts 104 may be formed by the lead finger 206 protruding through the molded top 102. A system contact 216 may be formed by the lead finger 206 protruding through the molded package body 214 at the bottom of the integrated circuit package system 100. A base package 218 may be formed by the lead frame 202, the integrated circuit die 208 and the electrical interconnects 212 encased in the molded package body 214.

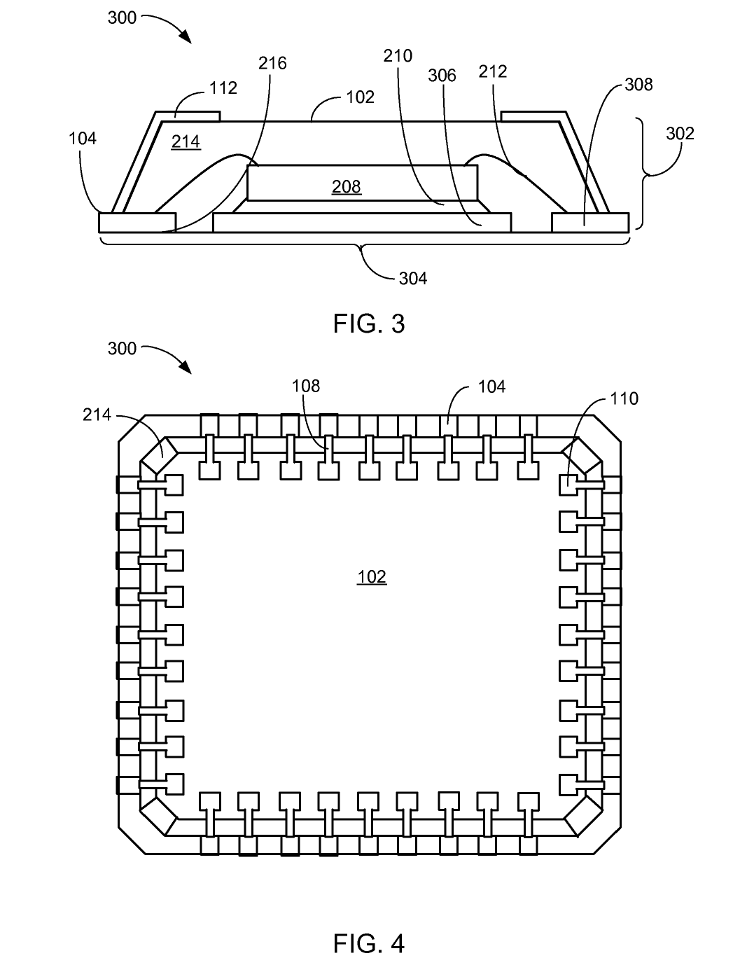

Referring now to FIG. 3, therein is shown a cross-sectional view of an integrated circuit package system 300 with distribution, in a first alternative embodiment of the present invention. The cross-sectional view of the integrated circuit package system 300 depicts a base package 302, such as a quad flat-pack no-lead (QFN), formed on a lead frame 304 having a die attach pad 306 and lead fingers 308. The integrated circuit die 208 may be mounted over the die attach pad 306 by the adhesive 210 and coupled to the lead fingers 308 by the electrical interconnects 212. The molded package body 214 may be formed on the lead frame 304, the integrated circuit die 208 and the electrical interconnects 212.

The surface contact 104 may be formed by the lead finger 308 protruding beyond the molded package body 214. Likewise the system contact 216 may be accessible at the bottom of the base package 302. The redistribution layer 112 may be formed from the surface contact 104 across the sloped profile of the base package 302 to the molded top 102. This configuration may provide an electrical connection between the system contact 216, the integrated circuit die 208 and the redistribution layer 112.

Referring now to FIG. 4, therein is shown a top view of the integrated circuit package system 300 of FIG. 3. The top view of the integrated circuit package system 300 depicts the molded top 102 formed above the surface contacts 104, as depicted in FIG. 3. The distribution trace 108 may be formed on the sloped sides of the molded package body 214 between the surface contact 104 and the redistribution chip pads 110.

It is understood that the number and position of the redistribution chip pads 110 is an example only the actual number and position may be different. It is further understood that having the redistribution layer 112 attached to every one of the surface contact 104 is also an example. The configuration of the redistribution chip pads 110, the distribution trace 108, and the redistribution contacts 106, of FIG. 1, will depend on the type of device (not shown) is intended to mount thereon.

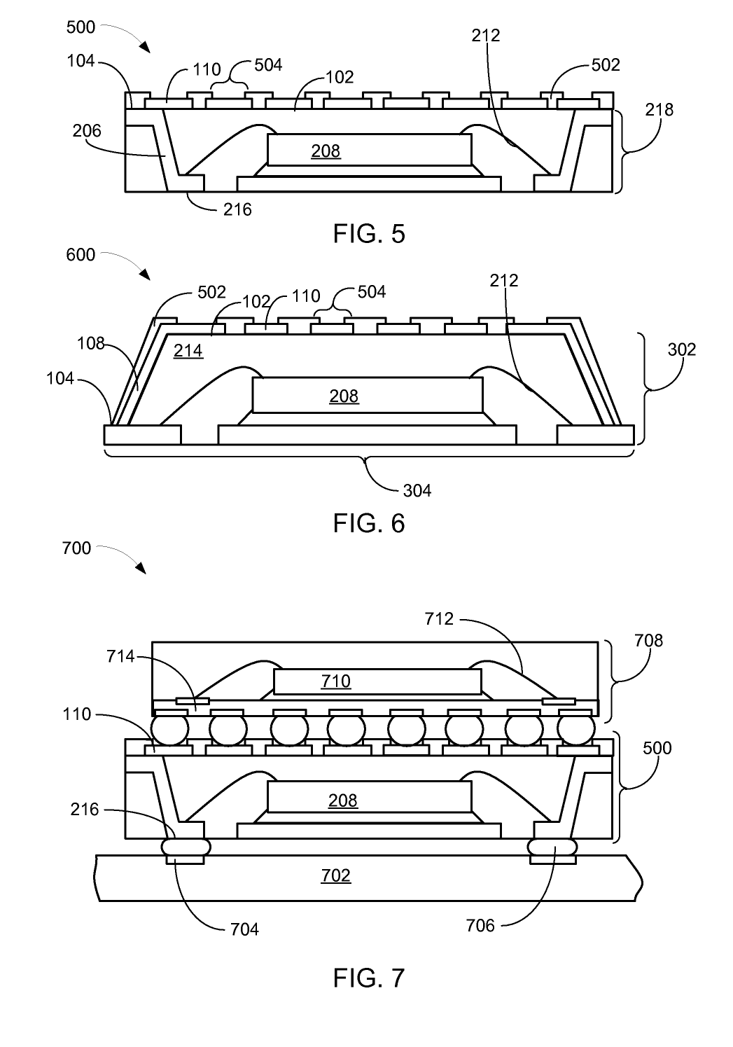

Referring now to FIG. 5, therein is shown a cross-sectional view of an integrated circuit package system 500 in a further embodiment of the present invention. The cross-sectional view of the integrated circuit package system 500 depicts the base package 218 having the integrated circuit die 208 coupled to the lead fingers 206 by the electrical interconnect 212. The surface contact 104 may have the redistribution chip pads 110 directly coupled. Further a number of the redistribution chip pads 110 may be distributed across the molded top 102.

Each of the redistribution chip pads 110 may have an electrical connection between the integrated circuit die 208, the system contact 216, or a combination thereof. An insulating layer 502, such as a solder mask, may be formed on and between the redistribution chip pads 110. The insulating layer 502 may provide an opening 504 over the redistribution chip pads 110 for connection of an electronic device, not shown.

It is understood that the use of the insulating layer 502 may be optional. It is further understood that the number and position of the redistribution chip pads 110 is an example only. In actual implementation, it is more likely to have a combination of the redistribution chip pads 110 and the distribution trace 108, of FIG. 1.

Referring now to FIG. 6, therein is shown a cross-sectional view of an integrated circuit package system 600 in a further embodiment of the present invention. The a cross-sectional view of the integrated circuit package system 600 depicts the base package 302 having the integrated circuit die 208, the electrical interconnects 212 and the lead frame 304. The surface contact 104 may have the distribution trace 108 formed on the slop of the molded package body 214 and coupled to the redistribution chip pads 110. Further a number of the redistribution chip pads 110 may be distributed across the molded top 102.

Each of the redistribution chip pads 110 may have an electrical connection between the integrated circuit die 208, the system contact 216, or a combination thereof. The insulating layer 502, such as a solder mask, may optionally be formed on and between the redistribution chip pads 110. The insulating layer 502 may provide the opening 504 over the redistribution chip pads 110 for connection of an electronic device, not shown.

It is understood that the use of the insulating layer 502 may be optional. It is further understood that the number and position of the redistribution chip pads 110 is an example only. In actual implementation, it is more likely to have a combination of the redistribution chip pads 110 and the distribution trace 108 intermixed on the molded top 102.

Referring now to FIG. 7, therein is shown a cross-sectional view of the integrated circuit package system 500 in a package on package stack 700. The cross-sectional view of the package on package stack 700 depicts a printed circuit board 702 having device pads 704 on the top surface. A system interconnect 706, such as a solder ball, a solder bump, a solder column, or stud bump, may couple the device pad 704 to the system contact 216 of the integrated circuit package system 500.

A stacked package 708, such as a ball grid array package, may be mounted over the integrated circuit package system 500 and electrically connected to the redistribution chip pads 110 by the system interconnect 706. An integrated circuit 710, such as a wire bond integrated circuit, a flip chip integrated circuit, or a combination thereof may be coupled by an electrical interconnect 712 to a package substrate 714.

The configuration of the stacked package 708 is an example only and any ball grid array package or lead frame package may be mounted over the integrated circuit package system 500. The number and position of the system interconnects 706 and the redistribution chip pads 110 is an example only and any number of the system interconnects 706 and the redistribution chip pads 110 may be used. In this configuration, an electrical connection may be made between the printed circuit board 702, the integrated circuit die 208, the integrated circuit 710, or a combination thereof.

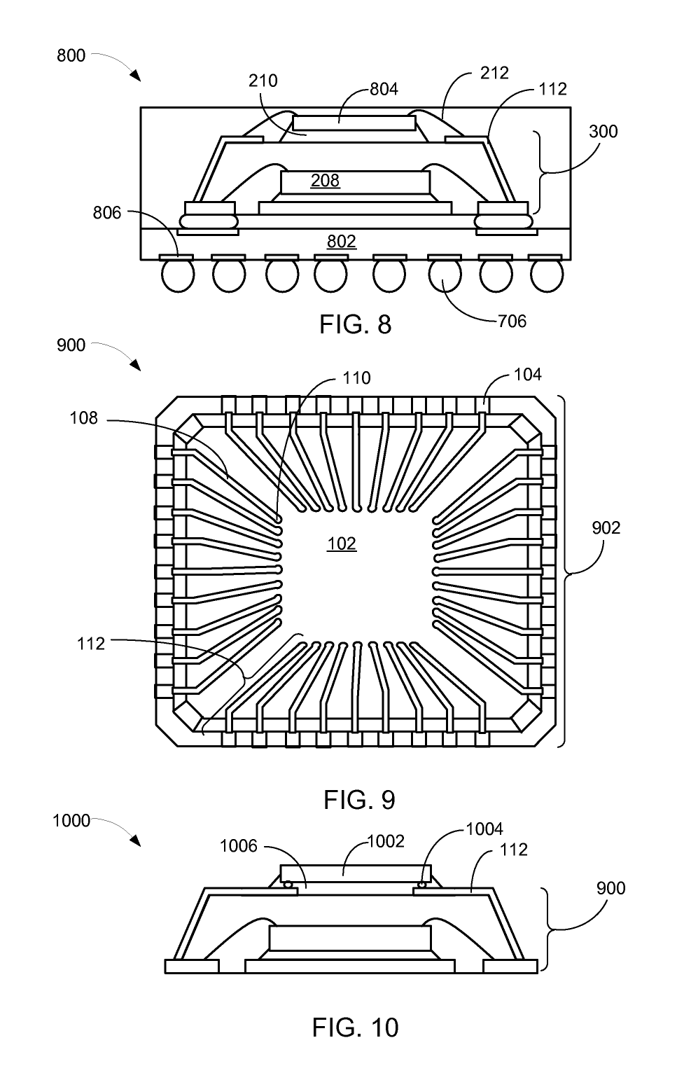

Referring now to FIG. 8, therein is shown a cross-sectional view of the integrated circuit package system 300 in a package in package stacked device 800. The cross-sectional view of the package in package stacked device 800 depicts the integrated circuit package system 300 mounted on a substrate 802 by the system interconnect 706. A stacked integrated circuit 804, such as a wire bond integrated circuit, a flip chip integrated circuit, or a combination thereof, may be mounted over the integrated circuit package system 300 by the adhesive 210. The electrical interconnects 212 may couple the stacked integrated circuit 804 to the redistribution layer 112.

A component pad on the substrate 802 may be electrically connected to the integrated circuit die 208, the stacked integrated circuit 804, system pads 806, or a combination thereof. The system pads 806 may be coupled to the system interconnects 706 for attachment to the next level system (not shown). A mold cap 808 may encase the integrated circuit package system 300, the stacked integrated circuit 804, the electrical interconnects 212, the system interconnects 706 and the top of the substrate 802.

Referring now to FIG. 9, therein is shown a top view of an integrated circuit package system 900 for fine pitch package attachment. The top view of the integrated circuit package system 900 depicts a quad flat-pack no-lead (QFN) package 902 having the distribution trace 108, coupled to the surface contact 104, converge the spacing of the redistribution chip pad 110 to provide for attaching a fine pitch device (not shown). The distribution trace 108 may be routed to any section of the molded top 102 of the QFN package 902. This process may allow attachment of a smaller wire bond die (not shown) or a flip chip integrated circuit (not shown) having only peripheral attaching pads.

The position and dimensions of the distribution traces 108 are by way of an example only and any number the distribution traces may form multiple device attaching points for connecting more than one device or combinations of devices including discrete components. The dimensions of the distribution traces 108 are an example only and any dimensions supported by the photo resist process are possible. The combination of the redistribution chip pad 110, the distribution traces 108, and the redistribution contacts 106, of FIG. 1, may form the redistribution layer 112.

Referring now to FIG. 10, therein is shown a cross-sectional view of the integrated circuit package system 900, of FIG. 9, in a device stack 1000. The cross-sectional view of the device stack 1000 depicts the integrated circuit package system 900 having a stacked chip 1002, such as a flip chip or wafer level chip scale product (WLCSP) mounted over the integrated circuit package system 900 and electrically connected to the redistribution layer 112 by chip interconnects 1004. The chip interconnects 1004 may be solder bumps, solder balls, solder columns, or stud bumps. Optionally, an under-fill material 1006 may be used to protect the chip interconnects 1004 and seal the active surface of the stacked chip 1002.

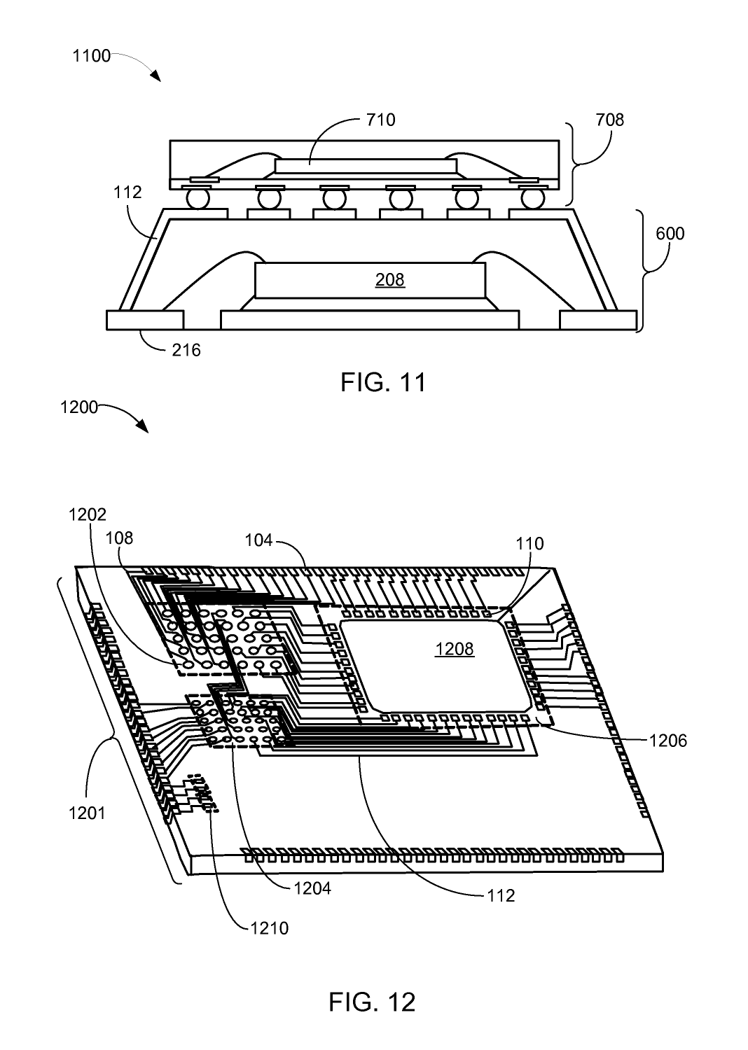

Referring now to FIG. 11, therein is shown a cross-sectional view of a package on package stack 1100 utilizing the integrated circuit package system 600. The cross-sectional view of the package on package stack 1100 depicts the integrated circuit package system 600 having the stacked package 708 mounted thereon. The integrated circuit 710 may be electrically connected to the integrated circuit die 208, the system contacts 216, or a combination thereof through the redistribution layer 112.

It is understood that the stacked package 708 may be any type of packaged device or multiple devices. The position of the redistribution chip pads 110 may be oriented to accept any package type including discrete components (not shown).

Referring now to FIG. 12, therein is shown a perspective view of an integrated circuit package system 1200 with redistribution, in an embodiment of the present invention. The perspective view of the integrated circuit package system 1200 depicts a quad flat-pack no-lead (QFN) package 1201 having the redistribution layer 112 configured thereon. The redistribution layer 112 may provide a ball grid array package site 1202 for connecting the stacked package 708, of FIG. 7, such as a ball grid array package. The dashed line around the ball grid array package site may be provided in the insulating layer 502, of FIG. 5. The redistribution chip pad 110 and the distribution traces 108 may provide an electrical connection to the surface contact 104 positioned along the edge of the QFN package 1201.

An integrated circuit attach site 1204 may provide a connection point for the stacked chip 1002, of FIG. 10, such as a flip chip integrated circuit or a wafer level chip scale package. The redistribution chip pad 110 may be of a smaller size to accommodate the chip interconnects 1004, of FIG. 10.

A leaded package site 1206 may be formed that may be suitable for attaching a quad flat pack, a quad flat-pack no-lead, a small outline tape package, or other package styles smaller than the QFN package 1201. A shield 1208, such as a ground shield may be positioned within the redistribution chip pad 110 outline of the leaded package site 1206. The shield 1208 may act as an electromagnetic interference (EMI) shield or a ground pad for attaching a wire bond integrated circuit.

A discrete component site 1210 may be formed for coupling resistors, capacitors, inductors, diodes, voltage regulators, crystal oscillators, or other devices that may not be suitable for inclusion in the integrated circuit technology. An aspect of this approach is that each of the devices coupled through the redistribution layer 112, of the present invention, may be packaged and tested as a normal device prior to assembly on the integrated circuit package system 1200.

This aspect will allow a higher end of the line yield than packaging untested parts in a multi-chip module. Another aspect of the integrated circuit package system 1200 is that the mounting of the additional tested components do not require additional area on the printed circuit board 702, of FIG. 7. It may also simplify the design of the printed circuit board 702 by reducing the number of interconnect networks required in the printed circuit board 702.

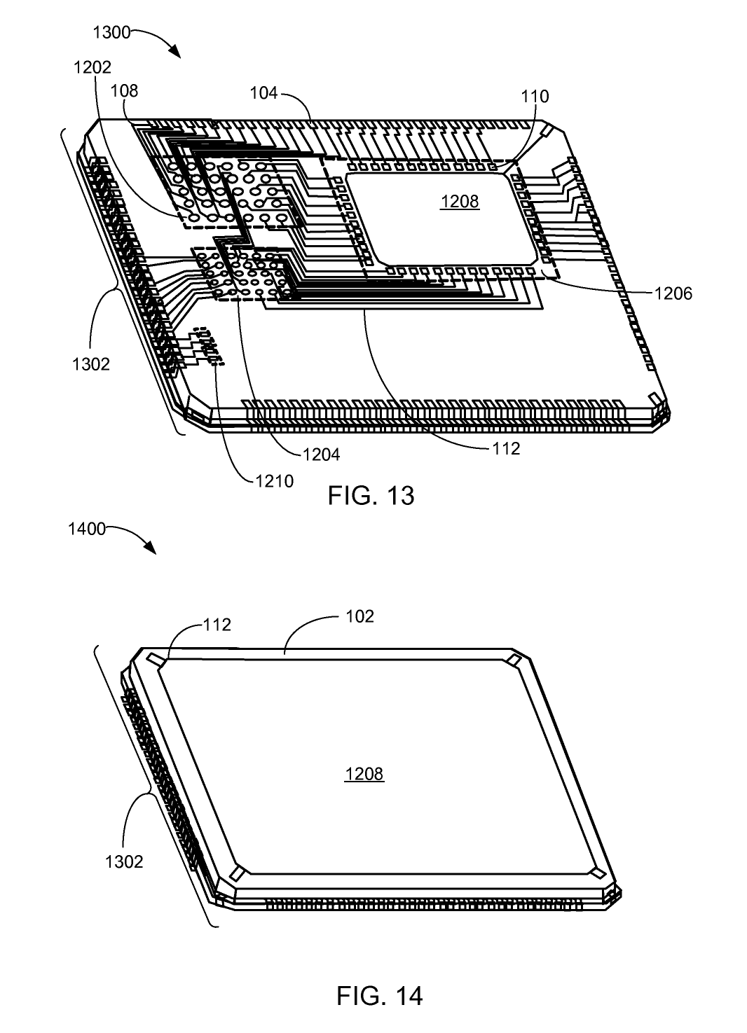

Referring now to FIG. 13, therein is shown a perspective view of an integrated circuit package system 1300 with redistribution, in an embodiment of the present invention. The perspective view of the integrated circuit package system 1300 depicts a quad flat pack (QFP) package 1302 having the redistribution layer 112 configured thereon. The redistribution layer 112 may provide the ball grid array package site 1202 for connecting the stacked package 708, of FIG. 7, such as a ball grid array package. The dashed line around the ball grid array package site may be provided in the insulating layer 502, of FIG. 5. The redistribution chip pad 110 and the distribution traces 108 may provide an electrical connection to the surface contact 104 positioned along the edge of the QFP package 1302.

The integrated circuit attach site 1204 may provide a connection point for the stacked chip 1002, of FIG. 10, such as a flip chip integrated circuit or a wafer level chip scale package. The redistribution chip pad 110 may be of a smaller size to accommodate the chip interconnects 1004, of FIG. 10.

The leaded package site 1206 may be formed that may be suitable for attaching a quad flat pack, a quad flat-pack no-lead, a small outline tape package, or other package styles smaller than the QFP package 1302. The shield 1208, such as a ground shield may be positioned within the redistribution chip pad 110 outline of the leaded package site 1206. The shield 1208 may act as an electromagnetic interference (EMI) shield or a ground pad for attaching a wire bond integrated circuit.

The discrete component site 1210 may be formed for coupling resistors, capacitors, inductors, diodes, voltage regulators, crystal oscillators, or other devices that may not be suitable for inclusion in the integrated circuit technology. An aspect of this approach is that each of the devices coupled through the redistribution layer 112, of the present invention, may be packaged and tested as a normal device prior to assembly on the integrated circuit package system 1300.

This aspect will allow a higher end of the line yield than packaging untested parts in a multi-chip module. Another aspect of the integrated circuit package system 1300 is that the mounting of the additional tested components do not require additional area on the printed circuit board 702, of FIG. 7. It may also simplify the design of the printed circuit board 702 by reducing the number of interconnect networks required in the printed circuit board 702.

Referring now to FIG. 14, therein is shown a perspective view of an integrated circuit package system 1400 with redistribution, in a second alternative embodiment of the present invention. The perspective view of the integrated circuit package system 1400 depicts the quad flat pack (QFP) package 1302 having the redistribution layer 112 configured thereon. The shield 1208 may be formed on the molded top 102, to partially or completely cover it. The surface contacts 104 may provide a ground through the tie bar of the QFP package 1302.

Optionally the distribution trace 108, of FIG. 1, may be patterned over the sloped edge of the QFP package 1302 to couple the surface contact 104 of specific ground leads (not shown). Providing a ground potential to the shield 1208 allows it to provide an EMI shield for the QFP package 1302.

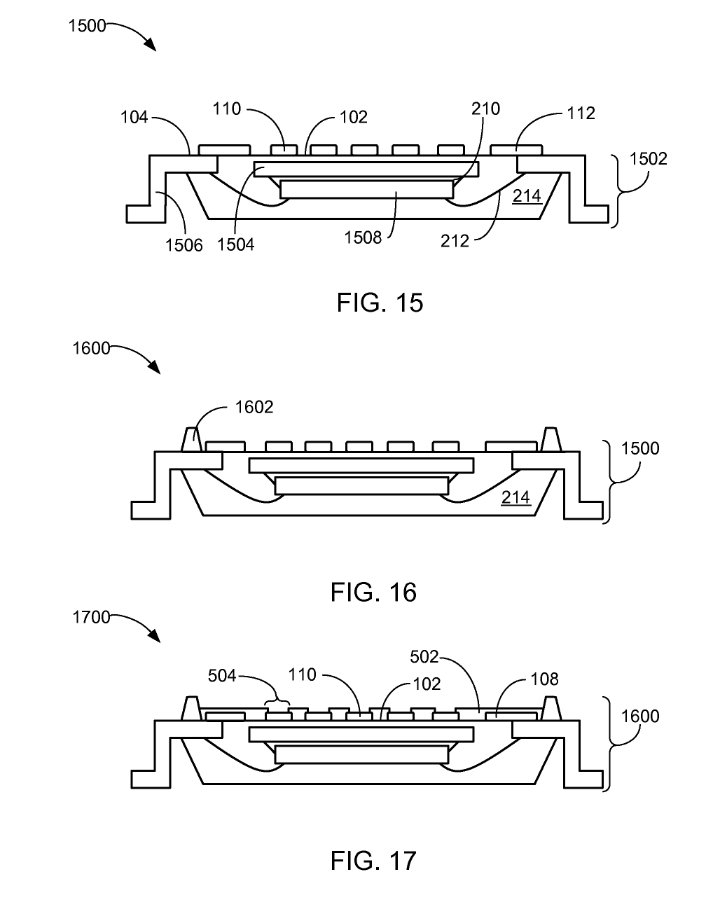

Referring now to FIG. 15, therein is shown a cross-sectional view of an integrated circuit package system 1500 in a third alternative embodiment of the present invention. The cross-sectional view of the integrated circuit package system 1500 depicts a half quad flat pack package 1502 having a die attach pad 1504 and lead fingers 1506. An integrated circuit die 1508 may be attached, in an inverted position, to the die attach pad 1502 by the adhesive 210. The electrical interconnect 212 may couple the integrated circuit die 1508 to the lead fingers 1506. The molded package body 214 may be formed on the die attach pad 1504, the integrated circuit die 1508, the lead fingers 1506, and the electrical interconnects 212.

The redistribution layer 112 may be formed on the surface contact 104 of the lead finger 1506 and the molded top 102 of the molded package body 214. The redistribution layer 112 may include the redistribution chip pad 110, the distribution traces 108 of FIG. 1, the redistribution contacts 106 of FIG. 1, or a combination thereof.

Referring now to FIG. 16, therein is shown a cross-sectional view of an integrated circuit package system 1600 in a first optional configuration of the third alternative embodiment of the present invention. The cross-sectional view of the integrated circuit package system 1600 depicts the integrated circuit package system 1500 having a lead forming support 1602 molded on the molded package body 214.

Referring now to FIG. 17, therein is shown a cross-sectional view of an integrated circuit package system 1700 in a second optional configuration of the third alternative embodiment of the present invention. The cross-sectional view of the integrated circuit package system 1700 depicts the integrated circuit package system 1600 having the insulating layer 502 on the distribution traces 108, the molded top 102, the redistribution chip pad 110, or a combination thereof. The opening 504 may be provided over the redistribution chip pad 110 for coupling an external device (not shown).

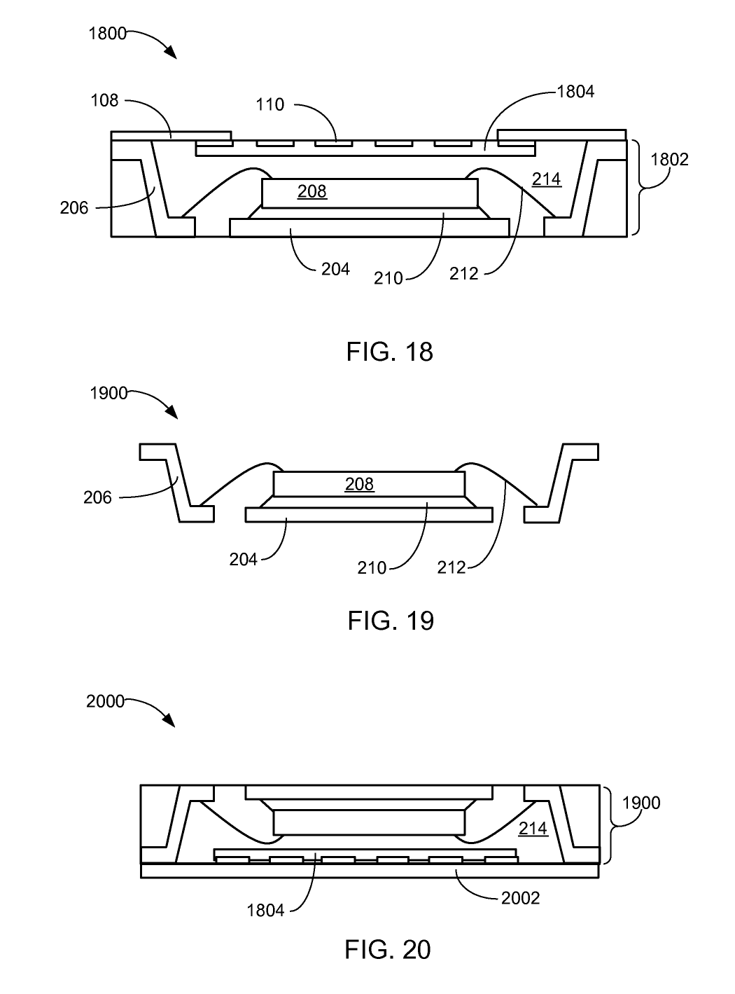

Referring now to FIG. 18, therein is shown a cross-sectional view of an integrated circuit package system 1800, in an alternative embodiment of the present invention. The cross-sectional view of the integrated circuit package system 1800 depicts a base package 1802 having the die attach pad 204 and the lead fingers 206. The integrated circuit die 208 may be attached to the die attach pad 204 by the adhesive 210. The electrical interconnects 212 may couple the integrated circuit die 208 to the lead fingers 206. The molded package body 214 may be formed on the die attach pad 204, the lead fingers 206, the integrated circuit die 208, the electrical interconnects 212 and a laminate transposer 1804.

The laminate transposer 1804 may provide the redistribution chip pads 110. The distribution traces 108 may be formed between the lead finger 206 and the redistribution chip pads 110 of the laminate transposer 1804. The laminate transposer 1804 may provide greater routing and interconnect capability than packages using just the redistribution layer 112, of FIG. 1.

Referring now to FIG. 19, therein is shown a cross-sectional view of an integrated circuit package system 1900 in an interconnect phase of manufacturing. The cross-sectional view of the integrated circuit package system 1900 depicts the die attach pad 204 with the integrated circuit die 208 mounted by the adhesive 210. The electrical interconnects 212 may couple the integrated circuit die 208 to the lead fingers 206. This represents a standard die attach and wire bond process.

Referring now to FIG. 20, therein is shown a cross-sectional view of an integrated circuit package system 2000 in a molding phase of manufacturing. The cross-sectional view of the integrated circuit package system 2000 depicts the integrated circuit package system 1900 in an inverted position. The laminate transposer 1804 may be positioned substantially under the integrated circuit die 208. The integrated circuit package system 1900 and the laminate transposer 1804 may be positioned on a coverlay tape 2002. The molded package body 214 may be formed on the integrated circuit package system 1900, the laminate transposer 1804 and the coverlay tape 2002.

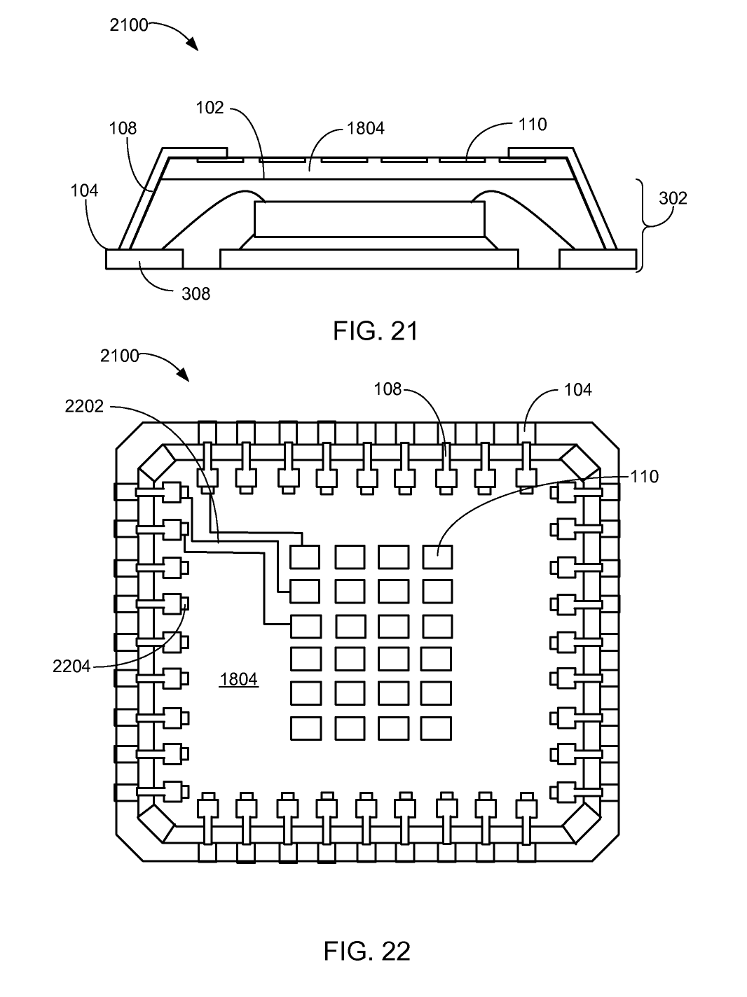

Referring now to FIG. 21, therein is shown a cross-sectional view of an integrated circuit package system 2100 in a fourth alternative embodiment of the present invention. The cross-sectional view of the integrated circuit package system 2100 depicts the base package 302 having the laminate transposer 1804 molded on the molded top 102. The distribution traces 108 may form an electrical connection between the surface contact 104 of the lead finger 308 and the redistribution chip pad 110 of the laminate transposer 1804.

Referring now to FIG. 22, therein is shown a top view of the integrated circuit package system 2100 of FIG. 21. The top view of the integrated circuit package system 2100 depicts the laminate transposer 1804 having the redistribution chip pads 110, interconnect traces 2202, and coupling pads 2204. The distribution trace 108 may electrically connect the surface contact 104 to the coupling pads 2204. The interconnect traces 2202 may route the coupling pads 2204 to the redistribution chip pads 110.

It is understood that the number and path of the interconnect traces 2202 is an example only and the actual implementation of the laminate transposer 1804 may be different. It is also understood that the number and position of the surface contacts 104, the distribution traces 108, the coupling pads 2204 and the redistribution chip pads 110 may be different.

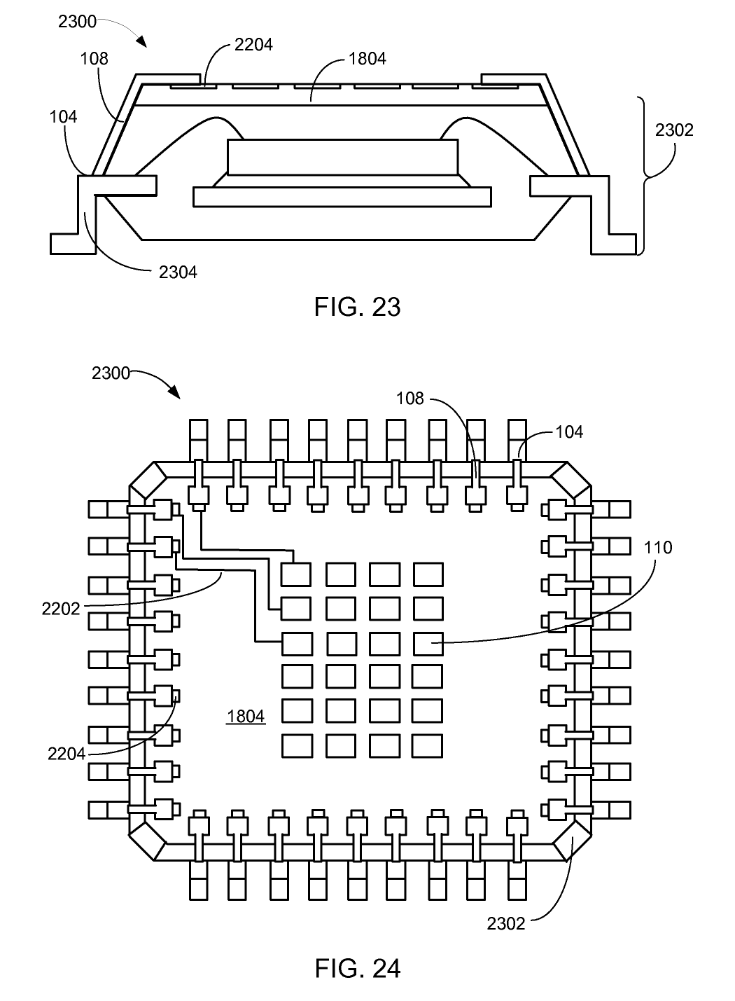

Referring now to FIG. 23, therein is shown a cross-sectional view of an integrated circuit package system 2300 in a fifth alternative embodiment of the present invention. The cross-sectional view of the integrated circuit package system 2300 depicts a quad flat pack package 2302 having the laminate transposer 1804 molded into the molded package body 214. The distribution traces 108 may couple the surface contacts 104 of a lead finger 2304 to the coupling pad 2204 of the laminate transposer 1804 for further distribution.

Referring now to FIG. 24, therein is shown a top view of the integrated circuit package system 2300 of FIG. 23. The top view of the integrated circuit package system 2300 depicts the laminate transposer 1804 having the redistribution chip pads 110, the interconnect traces 2202, and the coupling pads 2204 mounted over the quad flat pack package 2302. The distribution trace 108 may electrically connect the surface contact 104 to the coupling pads 2204. The interconnect traces 2202 may route the coupling pads 2204 to the redistribution chip pads 110.

It is understood that the number and path of the interconnect traces 2202 is an example only and the actual implementation of the laminate transposer 1804 may be different. It is also understood that the number and position of the surface contacts 104, the distribution traces 108, the coupling pads 2204 and the redistribution chip pads 110 may be different.

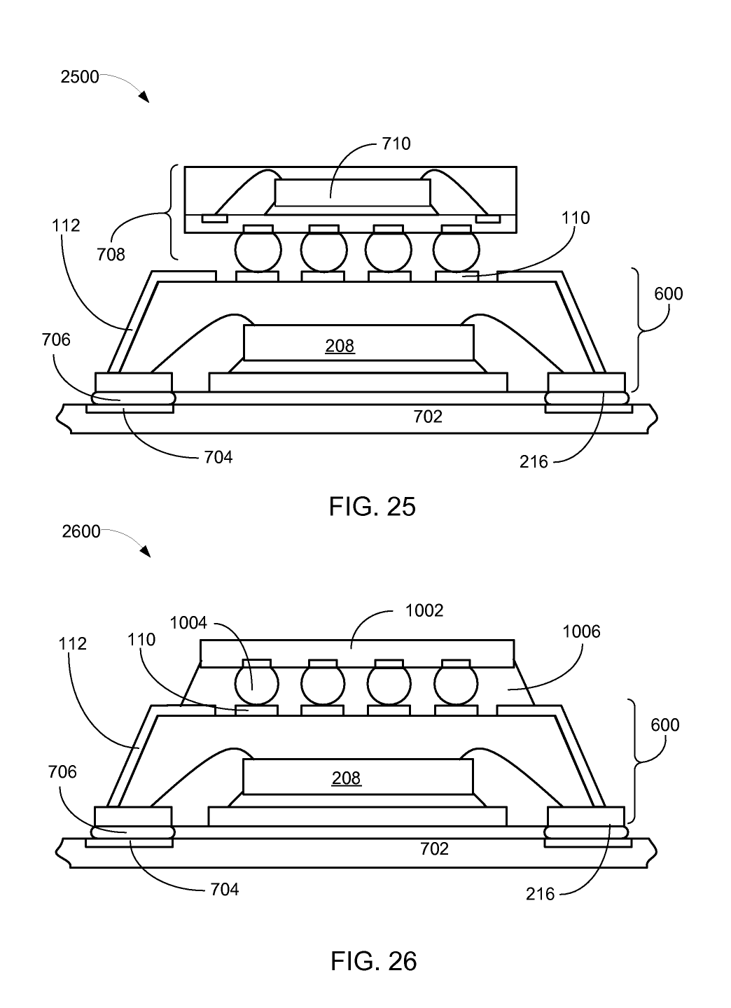

Referring now to FIG. 25, therein is shown a cross-sectional view of an integrated circuit package stack 2500 utilizing the present invention. The cross-sectional view of the integrated circuit package stack 2500 depicts the integrated circuit package system 600 having the stacked package 708 mounted thereon. The integrated circuit 710 may be electrically connected to the integrated circuit die 208, the system contacts 216, or a combination thereof through the redistribution layer 112.

The system contacts 216 may be coupled to the device pads 704 on the top surface of the printed circuit board 702. The system interconnect 706, such as a solder ball, a solder bump, a solder column, or stud bump, may couple the device pad 704 to the system contact 216.

It is understood that the stacked package 708 may be any type of packaged device or multiple devices. The position of the redistribution chip pads 110 may be oriented to accept any package type including discrete components (not shown).

Referring now to FIG. 26, therein is shown a cross-sectional view of an integrated circuit device stack 2600 utilizing the present invention. The cross-sectional view the integrated circuit device stack 2600 depicts the integrated circuit package system 600 having the stacked chip 1002, such as a flip chip or wafer level chip scale product (WLCSP) mounted over the integrated circuit package system 600 and electrically connected to the redistribution layer 112 by the chip interconnects 1004. The chip interconnects 1004 may be solder bumps, solder balls, solder columns, or stud bumps. Optionally, the under-fill material 1006 may be used to protect the chip interconnects 1004 and seal the active surface of the stacked chip 1002.

The stacked chip 1002 may be electrically connected to the integrated circuit die 208, the system contacts 216, or a combination thereof through the redistribution layer 112. The system contacts 216 may be coupled to the device pads 704 on the top surface of the printed circuit board 702. The system interconnect 706, such as a solder ball, a solder bump, a solder column, or stud bump, may couple the device pad 704 to the system contact 216.

It is understood that the stacked package 708 may be any type of packaged device or multiple devices. The position of the redistribution chip pads 110 may be oriented to accept any package type including discrete components (not shown).

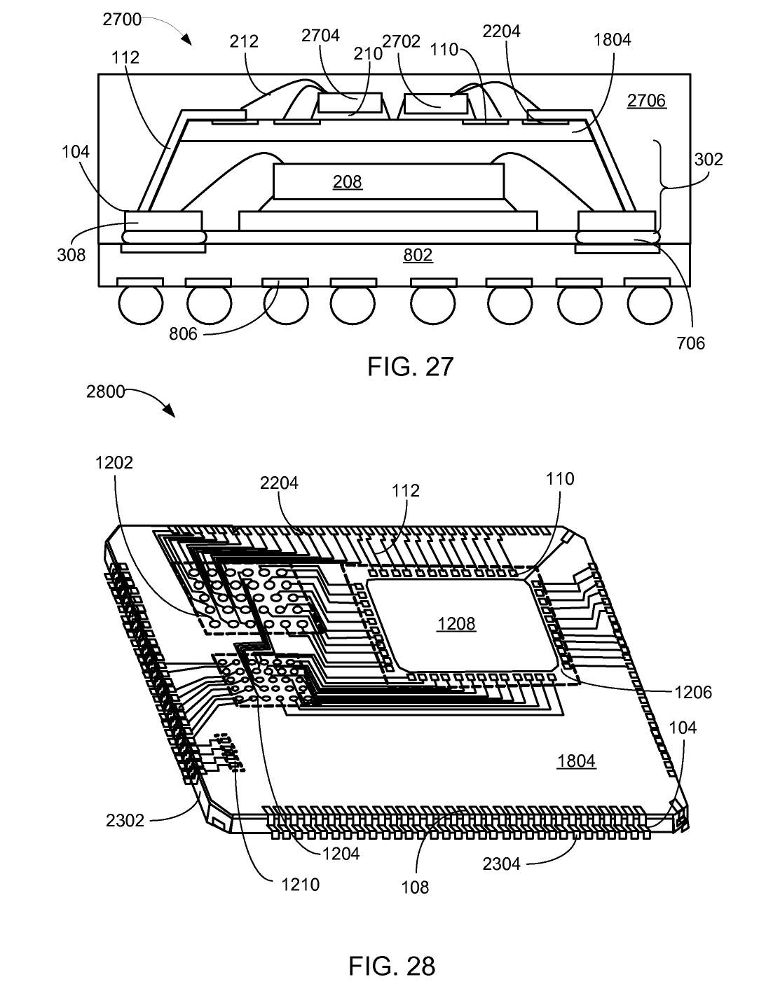

Referring now to FIG. 27, therein is shown a cross-sectional view of an integrated circuit package 2700 utilizing the present invention. The cross-sectional view the integrated circuit package 2700 depicts the base package 302 mounted on the substrate 802 by the system interconnect 706. The laminate transposer 1804 may be molded into the molded package body 214 of the base package 302. A first stacked integrated circuit 2702, such as a wire bond integrated circuit, a flip chip integrated circuit, or a combination thereof, and a second stacked integrated circuit 2704 may be mounted over the laminate transposer 1804 by the adhesive 210. The electrical interconnects 212 may couple the first stacked integrated circuit 2702 and the second stacked integrated circuit to the redistribution layer 112, the redistribution chip pads 110, or a combination thereof.

A component pad on the substrate 802 may be electrically connected to the integrated circuit die 208, the first stacked integrated circuit 2702, the second stacked integrated circuit 2704, the system pads 806, or a combination thereof. The system pads 806 may be coupled to the system interconnects 706 for attachment to the next level system (not shown). A mold cap 2706 may encase the base package 302, the laminate transposer 1804, the first stacked integrated circuit 2702, the second stacked integrated circuit 2704, the electrical interconnects 212, the system interconnects 706 and the top of the substrate 802.

Referring now to FIG. 28, therein is shown a perspective view of an integrated circuit package system 2800 with redistribution, in an embodiment of the present invention. The perspective view of the integrated circuit package system 2800 depicts the quad flat pack package 2302 having the laminate transposer 1804 molded into the molded package body 214, of FIG. 2. The distribution traces 108 may couple the surface contacts 104 of the lead finger 2304 to the coupling pad 2204 of the laminate transposer 1804 for further distribution.

The redistribution layer 112 may provide the ball grid array package site 1202 for connecting the stacked package 708, of FIG. 7, such as a ball grid array package. The dashed line around the ball grid array package site may be provided in the insulating layer 502, of FIG. 5. The redistribution chip pad 110 and the distribution traces 108 may provide an electrical connection to the surface contact 104 positioned along the edge of the QFP package 2302.

The integrated circuit attach site 1204 may provide a connection point for the stacked chip 1002, of FIG. 10, such as a flip chip integrated circuit or a wafer level chip scale package. The redistribution chip pad 110 may be of a smaller size to accommodate the chip interconnects 1004, of FIG. 10.

The leaded package site 1206 may be formed that may be suitable for attaching a quad flat pack, a quad flat-pack no-lead, a small outline tape package, or other package styles smaller than the QFP package 1302. The shield 1208, such as a ground shield may be positioned within the redistribution chip pad 110 outline of the leaded package site 1206. The shield 1208 may act as an electromagnetic interference (EMI) shield or a ground pad for attaching a wire bond integrated circuit.

The discrete component site 1210 may be formed for coupling resistors, capacitors, inductors, diodes, voltage regulators, crystal oscillators, or other devices that may not be suitable for inclusion in the integrated circuit technology. An aspect of this approach is that each of the devices coupled through the redistribution layer 112, of the present invention, may be packaged and tested as a normal device prior to assembly on the integrated circuit package system 2800.

This aspect will allow a higher end of the line yield than packaging untested parts in a multi-chip module. Another aspect of the integrated circuit package system 2800 is that the mounting of the additional tested components do not require additional area on the printed circuit board 702, of FIG. 7. It may also simplify the design of the printed circuit board 702 by reducing the number of interconnect networks required in the printed circuit board 702.

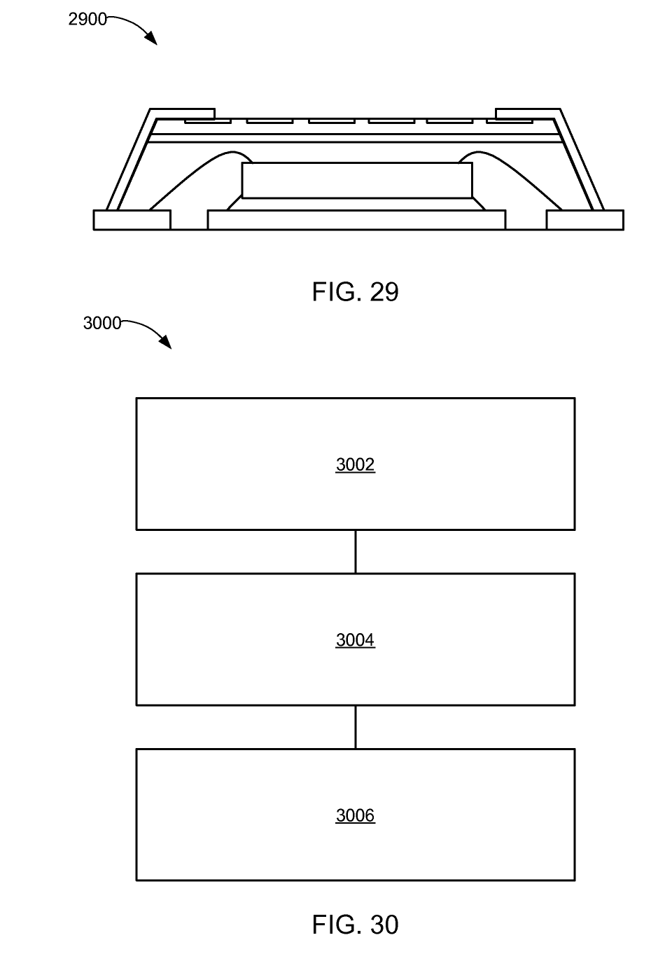

Referring now to FIG. 29, therein is shown a cross-sectional view of an integrated circuit application 2900 of the present invention. The cross-sectional view of the integrated circuit application 2900 depicts the base package 302 having the laminate transposer 1804 mounted thereon by the adhesive 210. The redistribution layer 112 may electrically connect the surface contact 104 with the coupling contact 2204 of the laminate transposer 1804.

This configuration will allow any previously manufactured integrated circuit package to be converted to a stackable interconnect structure that may save space on the printed circuit board as well as design time.

Referring now to FIG. 30, therein is shown a flow chart of an integrated circuit package system 3000 for manufacturing the integrated circuit package system 100 with redistribution in an embodiment of the present invention. The system 3000 includes forming a base package having a molded top in a block 3002; providing a surface contact on the base package in a block 3004; and patterning a redistribution layer on the molded top for coupling the surface contact in a block 3006.

An aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit package system of the present invention furnishes important and heretofore unknown and unavailable solutions, capabilities, and functional aspects for manufacturing multi-circuit package on package or package in package devices. The resulting processes and configurations are straightforward, cost-effective, uncomplicated, highly versatile and effective, can be surprisingly and unobviously implemented by adapting known technologies, and are thus readily suited for efficiently and economically manufacturing stacked integrated circuit devices fully compatible with conventional manufacturing processes and technologies. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. An integrated circuit package system comprising:
forming a base package having a molded top;
providing a surface contact on the base package; and
patterning a redistribution layer on the molded top for coupling to the surface contact.

2. The system as claimed in claim 1 further comprising providing an integrated circuit die in the base package for coupling to a stacked integrated circuit.

3. The system as claimed in claim 1 wherein patterning the redistribution layer includes depositing a metal, on the molded top, by chemical vapor deposition.

4. The system as claimed in claim 1 further comprising coupling a stacked integrated circuit to the redistribution layer includes coupling a wire bond integrated circuit, a flip chip integrated circuit, or a combination thereof.

5. The system as claimed in claim 1 further comprising applying a laminate transposer on the base package.

6. An integrated circuit package system comprising:
forming a base package having a molded top including forming a quad flat pack or a quad flat-pack no-lead package;
providing a surface contact on the base package including protruding a lead finger from the base package; and
patterning a redistribution layer on the molded top for coupling to the surface contact including forming a redistribution chip pad coupled to the surface contact.

7. The system as claimed in claim 6 further comprising providing an integrated circuit die in the base package for coupling to a stacked integrated circuit including coupling a system contact, the integrated circuit die, the stacked integrated circuit, or a combination thereof.

8. The system as claimed in claim 6 wherein patterning the redistribution layer includes depositing a metal, on the molded top, by chemical vapor deposition including depositing a copper, aluminum, or an alloy thereof.

9. The system as claimed in claim 6 further comprising coupling a stacked integrated circuit to the redistribution layer includes coupling a wire bond integrated circuit, a flip chip integrated circuit, or a combination thereof including coupling a wafer level chip scale package on the redistribution layer.

10. The system as claimed in claim 6 further comprising applying a laminate transposer on the base package including patterning a ball grid array package site, an integrated circuit attach site, a leaded package site, a shield, a discrete component site, or a combination thereof.

11. An integrated circuit package system comprising:
a base package having a molded top;
a surface contact on the base package; and
a redistribution layer on the molded top for coupling to the surface contact.

12. The system as claimed in claim 11 further comprising an integrated circuit die in the base package coupled to a stacked integrated circuit.

13. The system as claimed in claim 11 wherein the redistribution layer includes a metal deposited on the molded top by chemical vapor deposition.

14. The system as claimed in claim 11 further comprising a stacked integrated circuit coupled to redistribution layer includes a wire bond integrated circuit, a flip chip integrated circuit, or a combination thereof.

15. The system as claimed in claim 11 further comprising a laminate transposer on the base package.

16. The system as claimed in claim 11 further comprising:
a quad flat pack or quad flat-pack no-lead is the base package;
a lead finger protruded from the base package; and
a redistribution chip pad coupled to the surface contact.

17. The system as claimed in claim 16 further comprising an integrated circuit die in the base package coupled to a stacked integrated circuit includes a system contact, the integrated circuit die, the stacked integrated circuit, or a combination thereof coupled.

18. The system as claimed in claim 16 wherein the redistribution layer includes a metal, on the molded top, deposited by chemical vapor deposition includes copper, aluminum, or an alloy thereof deposited.

19. The system as claimed in claim 16 further comprising a stacked integrated circuit coupled to the redistribution layer includes a wire bond integrated circuit, a flip chip integrated circuit, a wafer level chip scale package, or a combination thereof on the redistribution layer.

20. The system as claimed in claim 16 further comprising a laminate transposer on the base package includes a ball grid array package site, an integrated circuit attach site, a leaded package site, a shield, a discrete component site, or a combination thereof patterned.
